(19) United States
(12) Patent Application Publication
(10) Pub. No.: US 2003/0181026 A1
(43) Pub. Date: Sep. 25, 2003

(54) Radiation-enhanced particle beams and related applications

(76) Inventors: Chungpin Liao, Taichung City (TW); Tsing-Tyan Yang, Tao Yuan Hsien (TW)

Correspondence Address: BIRCH STEWART KOLASCH & BIRCH, PO BOX 747, FALLS CHURCH, VA, 22040-0747, US

(21) Appl. No.: 10/173,097

(22) Filed: Jun. 18, 2002

(30) Foreign Application Priority Data
Mar. 21, 2002 (TW) 91105412

(51) Int. Cl. H01L 21/42

(52) U.S. Cl. 438/535

(57) ABSTRACT

Accelerators and implanters of nowadays are simply wasting too much energy on excitation of lattice electrons, rather than using energy on the desired nuclear scatterings. This current invention suppresses the undesired electronic stopping loss via causing effective neutralizing screening of the particles during their penetration through the target, using parallel speedy conduction electrons induced by assistant radiations. The assistant radiation beam of this invention can take the form of energetic electrons, X ray or γ ray, for example. One great advantage of the present invention is to further expand the application domains of existing accelerators and implanters, using readily available, relatively cheap and easy-to-implement radiation sources. The then saved particle energy will be redirected to reaching more depth or to rendering more defects within the target as desired. This invention is expected to bring great impacts on various application domains. In particular, it can greatly facilitate the electrical isolation among mixed-mode microelectronic integrated circuits, such as those on the system-on-a-chip (SOC), and bring to reality high-Q IC inductors on Si.

### FIELD OF INVENTION

The present invention relates to the method of achieving enhanced penetration of particle beams into target materials, and more particularly to techniques for creating local semi-insulating regions on semiconductor substrates, such as silicon, for achieving mixed-signal microelectronic circuit isolation and realization of high-Q inductors built on said substrates.

### BACKGROUND OF THE INVENTION

Particle beams (either in atomic or ionized states before impinging on (targets) have long been applied on various materials for many modifying and analyzing purposes. For example, impurity implantation into semiconductor substrates via ion implanter is a routine VLSI (very-large-scale integration) practice within semiconductor fabrication sites for the making of integrated circuits (lCs) on silicon substrates. Charged particle activation analysis (CPAA) of material constituents has been practiced for decades. High current proton (H⁺, or hydrogen ion) accelerators are now being developed to produce neutrons, via the ⁷Li(p,n)⁷Be or ⁹Be(p,n)⁹B nuclear reaction, for the achievement of a kind of cancer treatment, BNCT (boron neutron capture therapy) (see, e.g., Ludewigt B. A et al., 2001). (In the above nuclear reactions, the common notation A(a,b)B was used, in which the target nucleus “A” is bombarded by projectile (or radiation) “a” to become product nucleus “B” together with a released particle (or radiation) “b.” In addition, “p” and “n” stand for proton and neutron, respectively.) Recently, a new application has emerged, in which a penetrating ion (such as proton) beam was used for the creation of through-wafer local defects for the isolation of mixed-signal (analog-digital) circuit blocks and realization of high-Q inductors on a single silicon chip (U.S. Pat. No. 6,046,109 to Liao, Chungpin et al. (2000)). This same method was further employed in the creation of alternative SOI (silicon-on-insulator) structure (U.S. Pat. No. 6,214,750 to Liao, Chungpin (2001)). Lately, ion beams are even visualized as tiny sculpting tool in making nanopores (or molecular-scale holes) within materials such as Si₃N₄ for future electronic, chemical and biological purposes (Li J. et al., Nature, Vol. 412, p. 169, 2001).

Indeed, particle beams (in both neutral and ionized states) are so versatile, such that they can be employed in various scientific domains and engaged in newly developing frontiers. However, all existing old and new applications share a common limitation imposed by the beam-material interaction physics. Namely, under given circumstances, a particle beam's injection range into a target material is fixed, and can actually be calculated with reasonable accuracy by using, e.g., the much well-known computer code SRIM (The Stopping and Range of Ions in Matter, constantly updated by Ziegler J. F. and Biersack J. P., and available at Internet website: http://www.srim.org/). The physical reality is: in order to penetrate deep into a target material, the price to pay is to increase the particle beam energy, and therefore the accelerator or implanter capital cost. In practical applications, due to the involved technical complexity, higher energy usually means lower current and thus lower process throughput. For example, high energy implanters, for the making of microelectronic retrograde wells and buried layers for control of latchup in CMOS (complementary, metal-oxide-semiconductor) devices, have to go up to the energy level of 400 keV to several MeV, but with relatively low beam currents of only 0.005 to 0.05 mA (see, Wolf S. and Tauber R. N., Silicon Processing—for the VLSI era, Vol. 1, p. 314, Lattice Press, CA, 1986).

It is pointed out here, however, that this is because accelerators and implanters of nowadays are simply wasting too much energy on excitation of lattice electrons, rather than using energy on the desired nuclear scatterings. For example, especially for energies above several MeVs, an energetic particle passing through neutral atoms interacts mainly by means of the Coulomb force with the electrons in the atoms. Even though in each encounter the particle loses on the average not more than a few eVs of kinetic energy, ionization and excitation of atoms give the greatest energy loss per unit path length of the particle. The loss of kinetic energy in a nuclear encounter would be much larger, but such collisions are extremely rare compared to atomic (electronic) encounters, roughly in proportion to the area of cross section of a nucleus compared to that of an atom, i.e., 10⁻²⁴ cm²/10⁻¹⁶ cm²=10⁻⁸. Hence, nuclear collisions (or, scatterings) do not contribute appreciably to the overall energy loss. Therefore, as a particle traverses through a substrate, such as Si, a large fraction of its energy is consumed in lattice electron excitation and ionization (called electronic stopping), rather than in nuclear scattering (called nuclear stopping). The electronic stopping leads mainly to the undesirable radiation and heat, whereas the nuclear stopping renders the much desirable penetration or defect creation of our interest.

### SUMMARY OF THE INVENTION

It has been an object of the present invention to provide a method to extend energy-wise the application domains of accelerators and implanters without modifications to these facilities themselves.

A second object of the invention has been to provide a method to achieve deep doping, deep scattering analysis, efficient defect generation, and deep ion sculpting on various materials of interest using normal accelerators and implanters.

Another object of the invention has been to provide a method to greatly suppress the particle-beam-induced nuclear reaction decay effects, when performing existing particle beam applications.

Yet another object of the invention has been to provide an effective method to render isolation in analog-digital, analog-analog, and digital-digital integrated microelectronic circuits built on the same semiconductor chip, such as the SOCs (system-on-a-chip).

The last object of the invention has been to provide an economic method for realizing high quality IC (integrated circuit) inductors and transmission-lines on semiconductor substrates.

These objects are fulfilled by suppressing the undesired electronic stopping loss from the applied particle beam via causing effective neutralizing screening of the particles during their penetration through the target, using parallel speedy conduction electrons. It has been well known to the plasma physics and nuclear fusion community that as one charged particle is traversing an electron gas or plasma, those electrons at velocities much less than the particle velocity barely interact with the particle. It is those having velocities close to the incident particle velocity that interact collectively with the particle and thus screened the latter. This fact has been utilized in various plasma heating schemes for fusion reaction, such as the current drive and the neutral beam injection.

In the derivation of existing working particle stopping formula, such as those by Lindhard, Brandt, Kitagawa, and Ziegler (see, e.g., Ziegler J. et al., The Stopping and Range of Ions in Solids, Pergamon Press, (1985)), material targets are also viewed as plasmas characterized by collective behaviors. The Lindhard theory is especially accurate in the range of about 200 keV/amu to 10 MeV/amu (Ziegler J. et al., 1985), where amu stands for atomic mass unit, and is roughly equal to the atomic weight of the projectile, e.g., the proton's amu is about 1. For the current invention, the externally supplied assistant radiation beam (see FIG. 1 for setup) is to either speed up the existing target conduction electrons or to overshadow them with newly generated ones. A quantitative demonstration of the importance of relative velocity between the beam particles and target conduction electrons will be offered after looking into the following stopping power formula.

The quantitative picture related to the aimed purpose can be understood from the following stopping power (−dE/dx) representation:

$$- ( \frac{ⅆ E}{ⅆ x} ) = n [ {S}_{n} ( E ) + {S}_{e} ( E ) ] ( J \text{/} m ) \qquad ( 1 )$$

where E is the projectile energy, n is the atomic number density of the target material, and Sₙ and Sₑ are the unit-path nuclear and electronic scattering losses, respectively. The invented method is to greatly reduce the second term on the right hand side, by reducing the effective charge state of the incident particle. For example, when the projectile energy is in the so-called Bethe-Bloch regime (i.e., high energy, above several MeV, but non-relativistic) for the aforementioned isolation purpose on Si chips, the corresponding existing electronic stopping power formula of inelastic scattering has been derived as (from: Meyerhof W. E., Elements of Nuclear Physics, p. 77, McGraw-Hill Book Co., 1967, but in S1 unit):

$${( - \frac{ⅆ E}{ⅆ x} )}_{e} \approx \frac{{e}^{4} {z}^{2} nZ}{4 π {ϵ}_{0}^{2} {m}_{0} {v}^{2}} \cdot ln \frac{2 {m}_{0} {v}^{2}}{{I}_{ave}} ( J \text{/} m ) \qquad ( 2 )$$

where

ze=charge of the energetic particle

m₀=mass of electron

v=speed of the energetic particle

nZ=electron number density in the stopping material

Iₐᵥₑ=mean ionization and excitation potential of the atoms in the stopping material≈13·Z eV

If z of the right hand side of equation (2) can be reduced by a multiplication factor f (f being less than unity) as a result of the assistant-radiation-induced charge screening of the incident projectile, then the associated electronic stopping loss of the penetrating particle beam can be quadratically decreased. (Note that for this high-velocity case of interest, i.e., 2Z₁/137β<1 (β=v/c), the classical pictures such as the impact parameter, as well as arguments to formally arrive at equation (2) are no longer valid, and more seriously, misleading and puzzling. Only fully quantum mechanical, collective wave-type derivation and interpretation are correct (see, e.g., Evans R. D., The Atomic Nucleus, p. 584-586, McGraw-Hill, 1955).) This now makes us ready for quantitative demonstration of the importance of relative velocity between the beam particles and target conduction electrons, that is, the enhanced polarization screening of incident particles.

In all derivations of electronic stopping cross sections, which proved to be good approximations to experimental data, an important consideration is the relative velocity of the incident particle's electrons to those in the target (see, e.g., Ziegler J. et al., The Stopping and Range of Ions in Solids, Chap. 3 and Appendix 1, Pergamon Press, (1985)). It is found that a good approximation is that electrons are stripped from the incident ion when their mean velocity falls below that of the conduction electrons in the solid. The conduction electrons are assumed to be a free electron gas (plasma) and they have a Fermi velocity (ν_{F}=η/m(3π²N)^{1/3}) based on the target electron number density N at low temperature (close to 0 K), where □ and m are Planck constant divided by 2π and electron rest mass, respectively. The Fermi velocity of a quantized electron gas (simplification of solid, used in today's working stopping formulas) is the electron velocity of the highest occupied energy level, or conduction electrons. It has been experimentally confirmed that the effective charge fraction of the incident particle within a target is (see: Ziegler J. et al., ibid):

$$q = 1 - exp ( - \frac{0.92 {v}_{r}}{{v}_{0} {z}_{1}^{2 / 3}} ) \qquad ( 3 )$$

where z₁ is atomic number of incident particle, νᵣ≡

$$( {v}_{F} = \frac{n}{m} {( 3 {π}^{2} N )}^{1 / 3} )$$

is the relative speed between the incident ion (velocity \vec{ν}) and target conduction electrons (velocity \vec{ν}ₑ), whereas v₀ (≈2.2×10⁸ cm/s, or in energy: ˜25 keV/amu) is a quantity called Bohr velocity. It is obvious that when vᵣ is large, q=1; while q can be greatly reduced when vᵣ is small, and the projectile becomes quasi-neutral. Traditionally, the latter situation (i.e., reduced electronic stopping) takes place only when the projectile velocity is close to the Fermi velocity of the target, i.e., 1<(vₑ/v_{F})<5. FIG. 3 shows that the location of inflection point of electronic stopping (i.e., decrease in e-stopping) for a particle is where its velocity equals the Fermi velocity of an electron gas, as indicated by the arrows (from: Ziegler J. et al., The Stopping and Range of Ions in Solids, p. 71, Pergamon Press, (1985)). In fact, though at the other end of the energy spectrum, this is also why when the particle energy is relatively low (e.g., 10-800 keV, as in the interest of routine VLSI impurity implantation processes) the corresponding electronic stopping formula has been known to be in the form (from Wolf S. and Tauber N., Silicon Processing, Vol. 1, p. 288, Lattice Press, 1986):

$${( - \frac{ⅆ E}{ⅆ x} )}_{e} = {KE}^{0.5} ( J \text{/} m ) \qquad ( 4 )$$

where the proportional constant K depends only weakly on the projectile and target atomic masses and numbers (see FIG. 2 for plots of several projectile species). This is because, at such low energy, the charge screening effect on projectiles is predominant, which leads to the observed nearly projectile- and target-independent consequence. Now back to the high energy end (which is of particular interest to the current invention), FIG. 3 of the electronic stopping power versus the electron number density illustrates this same point well (see: Ziegler J. et al., Chap. 3 (1985)). Namely, charge screening of the high energy projectile also gives rise to the indicated inflection of stopping power curves (ie., decrease in e-stopping). However, recalling that v_{F}∞N^{1/3}, the needed projectile velocity is undesirably high. Even if this is achieved, still the target conduction electrons are in random motion. That is, after averaging over all directions of electron motion, vᵣ is found to be larger than the projectile speed v, rather than being nearly zero (see: Ziegler J. et al., ibid), making q→0 a realizable event, after all, only at low energy.

Now, instead of being limited by the solid electron number density, or in essence the Fermi velocity, the current invention employs external radiation to control the conduction electron velocity, such that it is at prescribed value, largely unidirectional, and parallel to the incident particle beam. This makes vᵣ=|v−vₑ| less (instead of larger) than both v and v₀, and thus q less than 1, or even close to zero. Thus, the current invention in effect extends the validity of projectile neutralization (as described by equation (3)) to higher particle energy. This is because the supreme value of vₑ is now not the Fermi velocity but the prescribed velocity determined externally. In fact, even externally generated fast moving electrons, instead of those original conduction electrons, can serve our purpose as well. As a result of this, from equation (2), the undesired electronic stopping loss suffered by the particle beam can be considerably reduced, in a wider energy range. FIG. 4 shows that the inflection point of stopping power for a particle is now shifted to where its velocity equals that of those externally driven new “conduction” electrons. In other words, the electronic stopping power curve in FIG. 3 now bends (or flattens out) not at the unrealistically high target electron number density, but at much favorably lower relevant electron density (illustrated in FIG. 4).

The assistant radiation beam of this invention can take the form of energetic electrons, X ray or γ ray, for example. And, while useful, proper masking of target from the above radiation can either be applied or not applied, depending on the results required. One great advantage of the current invention is to further expand the application domains of those technically complicated as well as expensive existing accelerators and implanters, using readily available, relatively cheap and easy-to-implement radiation sources. For example, radioactive decay generated γ ray consumes no electric power. The then saved particle energy will be redirected to reaching more depth or to rendering more defects within the target as desired. Or, with the new opportunity to use less energy owing to this energy saving, great benefit of much less radioactive decay effects can be expected, as now the lower accelerator or implanter energy causes much less nuclear reaction within the target. For example, it takes about 4 MeV to bring together a proton and a Si nucleus to ignite a likely nuclear reaction. For proton energy less than the threshold energy, there is essentially no nuclear reaction.

In the low energy regime, nuclear stopping is significant and the crossover energy at which electronic stopping (described by equation (4)) becomes more effective than nuclear stopping is higher for heavier ions. For example, for boron (¹¹B), electronic stopping is the predominant energy loss mechanism down to ˜10 keV in Si; while for phosphorus (³¹P) and arsenic (⁷⁵As), the energy loss due to nuclear stopping predominates for energies up to 130 keV and 700 keV, respectively (see FIG. 2). The invented method can render further charge neutralization of the incident particle. Thus, e.g., a 100-200 keV boron implanter can readily enjoy enhanced penetration range by applying the invented method. As for P and As implants, such benefits can be expected when working above about 1 MeV.

### BRIEF DESCRIPTION OF THE DRAWINGS

FIG. 1 illustrates one setup of a general radiation-enhanced particle beam of the invention;

FIG. 2 shows existing calculated values of dE/dx for As, P, and B at various energies (reprinted from Wolf S. and Tauber N., Silicon Processing, Vol. 1, p. 288, Lattice Press, 1986);

FlG. 3 shows the electronic stopping power of a particle in an electron gas cloud, in which the inflection point for a particle is where its velocity equals the Fermi velocity of an electron gas as indicated by the arrows above (from: Ziegler J. et al., The Stopping and Range of Ions in Solids, p. 71, Pergamon Press, (1985);

FIG. 4 shows the electronic stopping power of a particle in an externally influenced electron gas cloud (current invention), in which the shifted inflection point for a particle is where its velocity equals that of those externally driven new “conduction” electrons within the electron cloud;

FIG. 5 shows the effect of general radiation-assisted proton (H⁺) beam in penetration range into silicon by comparing with that of without assistant radiation;

FIG. 6 shows the energy vs. range relation of an energetic electron impinging upon Si (converted from the relevant figure in Knoll G. F., Radiation Detection and Measurement, p. 59, John Wiley & Sons, 1979);

FIG. 7 shows the angular distribution of Compton-scattered X/γ-ray (incident from the left) according to the Klein-Nishida formula (from: Meyerhof W. E., Elements of Nuclear Physics, p. 96, McGraw-Hill, 1967); and

FIG. 8 shows the simulated energy-depth scenario of a radiation-assisted 200 keV boron into silicon, in comparison with that of traditional boron implantation.

### DESCRIPTION OF THE PREFERRED EMBODIMENTS

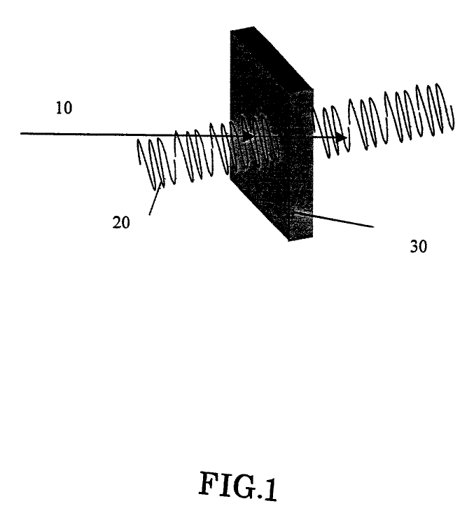

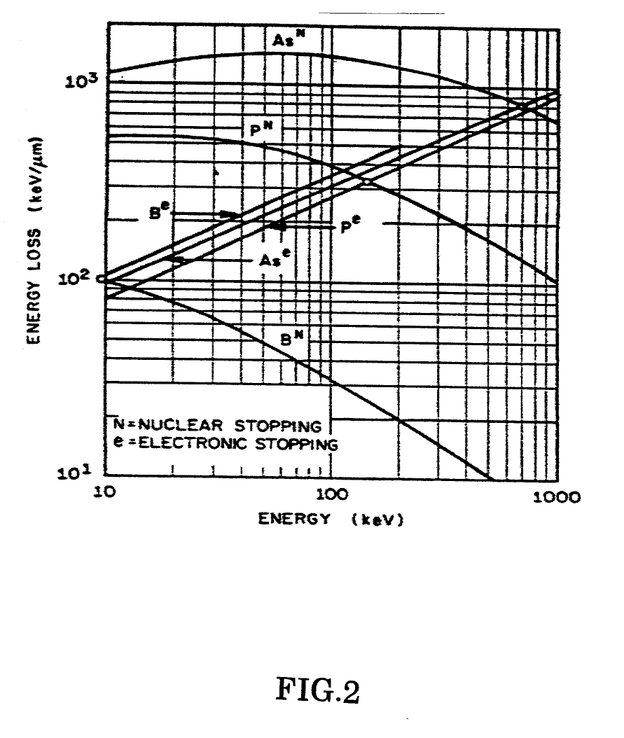

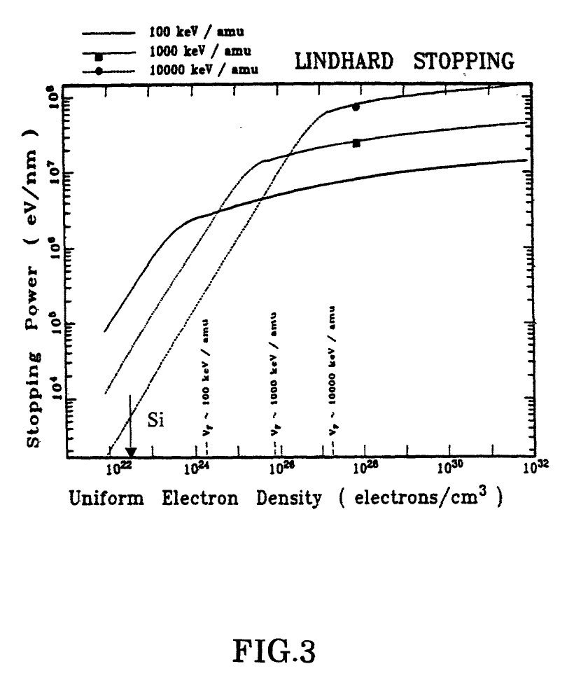

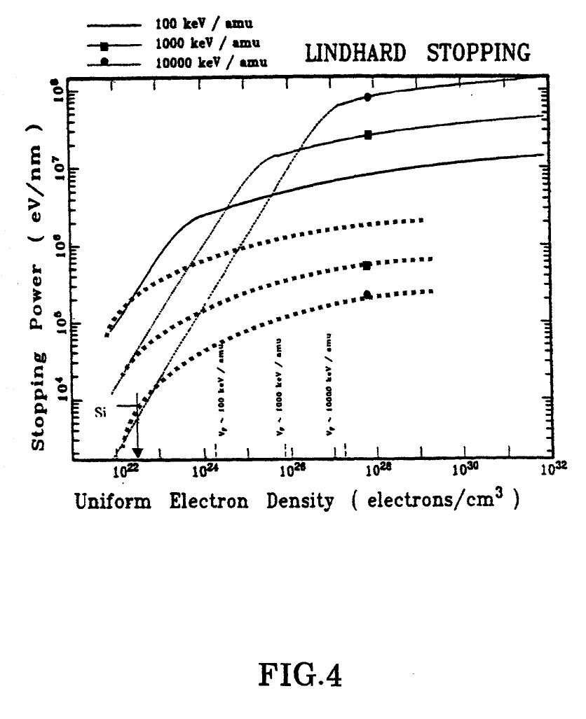

In the invented method (see FIG. 1), incident particle beam 10 onto target 30 is assisted by the combining radiation beam 20, which can take the form of, e.g., an energetic electron beam, X ray, or γ ray, etc., and can be in traveling wave form or standing wave pattern. Particle beam 10 and radiation beam 20 can each be arranged roughly parallel to each other, and at desirable angle with respect to the room floor, to fit in different practical conditions. In the following, several preferred embodiments relating to circuits isolation on SOC (system-on-a-chip) and high-energy implantation (doping) are presented in which the required assistant radiation characteristics are calculated and elaborated.

It is worth mentioning here that although the charge neutralization formula (equation (3)) has been proven effective for heavy (z>2) ion beams, there are, after so many decades, still controversy and debates over the legitimacy of partial charges for hydrogen and helium. So far, no one could propose a way to directly measure the charge state of protons in solids, while various indirect experiments up to this day only gave rise to many discrepancies. It is commonly argued by some that it is unlikely that protons should possess a bound electron at any velocity since the electronic radius should be larger than the nearest atom in the solid. However, like a lot of others, we counter this argument by noting that because a bare proton will collectively polarize the target electron plasma, it still will have a virtual bound electron. In addition, we are familiar with the proton neutralization effect, as described by equation (4), during the low energy portion of its journey within a target.

1. Electron-beam-enhanced Proton Beam for Deep Penetration into Si or SiGe

This embodiment is related to the practical purpose of achieving high-Q IC inductors and isolation of mixed-signal circuits built on the same semiconductor substrate, such as Si, SiGe, or the latest SiGeC, using the invented radiation-enhanced proton beam. When the substrate resistivity is greatly increased (to about 10⁵-10⁶ Ω-cm) by proton beam bombardment prior to IC packaging, it ceases to be a conducting path for interfering signals (see: Liao, Chungpin et al., “Method of creating local semi-insulating regions on silicon wafers for device isolation and realization of high-Q inductors,” IEEE Electron Device Letters, 19(12), 461, 1998). And, the resultant suppression of transient leakage currents, and hence AC losses, greatly improves the quality factors (Q values) of IC inductors (Liao et al. ibid). In this embodiment, the assistant radiation takes the form of energetic electron beam.

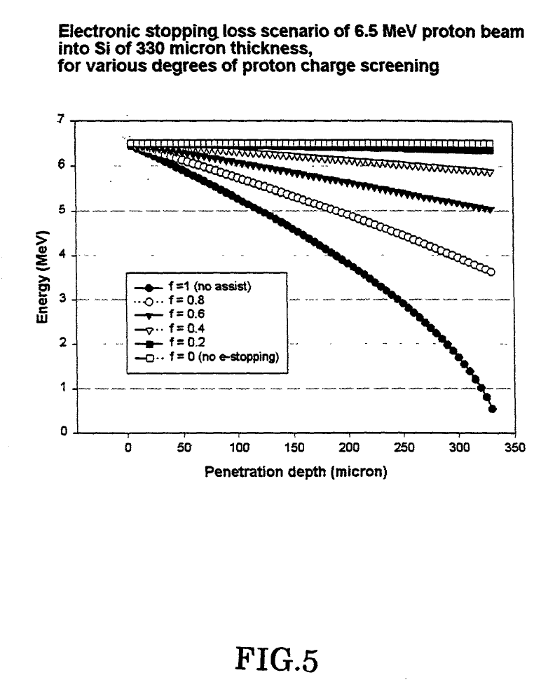

For Si IC chips thinned to about 330 μm prior to packaging, the minimum proton energy required to penetrate through such thickness is about 6.5 MeV according to SRIM calculation. A practical energy-depth scenario, of a 6.5 MeV proton beam penetrating into a Si chip of about 330 μm thickness for SOC isolation, with respect to different values of f (projectile charge reduction factor), is calculated and shown in FIG. 5, through numerically integrating equation (2). It can be seen that in its total range of about 330 μm within Si, the proton beam spends only about 0.5 MeV in the desired nuclear stopping, while wasting all other 6 MeV in the electronic stopping. Also, significant projectile energy saving can readily be secured even with a slight charge screening (f=0.8, thus f²=0.64) of the particles, as compared with the traditional sole ion beam bombardment (f=1).

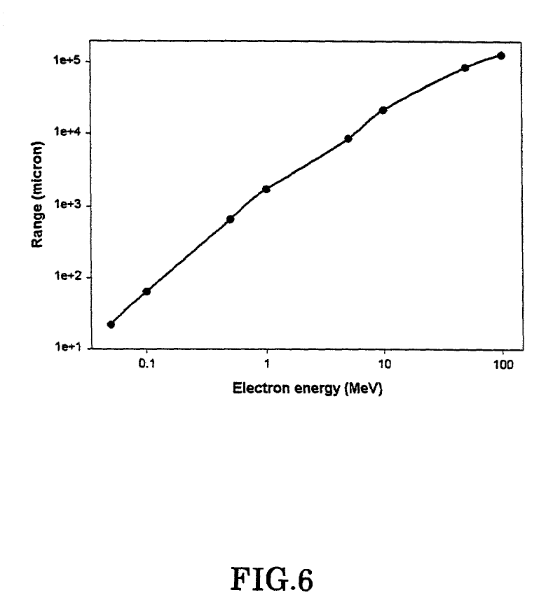

In this example, the energetic electron beam has to possess the energy of about 0.5 MeV to penetrate the Si chip of interest (as referred from FIG. 6). These beam electrons are employed to ignite the cascade of electrons, which overshadow and thus replace existing target conduction electrons in fulfilling the purpose of screening the incident particle beam. Since the conduction electron number density N at low temperature can be as low as 10⁵ cm⁻³, close to the proton number density, the needed current for the assistant 0.5 MeV e-beam may be chosen, for example, to be the same or less than that of the proton beam (say, 50-200 μA) to facilitate the proton charge neutralization. Note that a 0.5 MeV electron carries a velocity much larger than the average proton in this embodiment.

The binding energy E_{b} of a K-shell electron in Si can be obtained from the Hartree theory to be E_{bK}≈(Z−1)²·E_{hydrogen}=(14−1)²·13.6 eV=2.3 keV, where E_{hydrogen} is the binding energy of the single electron in hydrogen atom. The average Si lattice electron binding energy E_{b} is known to be E_{b}≈Z·E_{hydrogen}=14·13.6 eV=190 eV (the above see, e.g., Meyerhof W. E., Elements of Nuclear Physics, p. 77 & 99, McGraw-Hill, 1967). If it is assumed that all 0.5 MeV electrons first ionize 0.5 MeV/2.3 keV≈200 K-shell electrons, which then cause cascading electrons moving at close to the incident ˜MeV proton velocity (i.e., ½ mₑvₑ²˜600 eV), we obtain a new “conduction” electron density of (I/evA)·200·2.3 keV/(600 eV/electron)≈5·10⁷ cm⁻³ ( [symbol] 10⁵ cm⁻³), enough for the screening purpose. This all happens within the proton transit time of about 12 ps (=10⁻¹² s) through the Si target, where v and A are the beam electron speed and beam cross-sectional area, respectively.

For the best result (i.e., ideal case of fill screening), the now required energy of the proton beam would be merely 0.5 MeV (instead of 6.5 MeV) to satisfy the purpose of this example. This implies great saving in particle beam equipment and new opening of opportunities for various large-current applications. On the other hand, the required electron beams in the energy range of interest are relatively cheap and easy to acquire.

Concerns over possibly notable excitation loss as a result of interaction between proton and electron beams themselves will not materialize. This is because high relative speed and low densities make the loss, if any, minimal, according to equation (2).

The applied electron beam power of about 0.5 MV·50 μA=25 W presents no difficulty to existing cooling technology, if maintaining the target in certain temperature range is desired. Or, a rotational scanning treatment on a batch of properly masked IC chips or wafers can be arranged if needs be.

2. X/γ-ray-assisted Proton Beam for Deep Penetration into Si or SiGe

In this second embodiment, the assistant radiation takes the form of X-ray or γ-ray. Similar to the first embodiment, it is related to the practical purpose of achieving high-Q IC inductors and isolation of mixed-signal circuits built on the same semiconductor substrate, such as Si, SiGe, or the latest SiGeC.

The existing knowledge of attenuation coefficients of X-ray and γ-ray within Si is tabulated below:

TABLE 1
X/γ-ray attenuation coefficient within Si

| | | | Attenuation coefficient | | | Max. angle |
|---|---|---|---|---|---|---|
| Energy | | Wavelength | (cm⁻¹) | Attenuation length | | of photoelectrons* |
| 1 | keV | 12.4 Å | 3743.8 | 2.7 | μm | 180° |
| 10 | keV | 1.24 Å | 78.5 | 127.4 | μm | 180° |
| 100 | keV | 0.12 Å | 0.40 | 2.5 | cm | 160° |
| 500 | keV | 0.024 Å | 0.25 | 4.0 | cm | 90° |
| 1.25 | MeV | 0.001 Å | 0.13 | 7.6 | cm | 50° |

*with respect to the direction of incident X/γ-ray

Note that there is no clear boundary between X-ray and γ-ray in terms of their energy content. In general, 1-50 keV is dominated by X-ray sources, while γ-ray covers the energy spectrum above 50 keV. In addition, while X-ray is routinely generated artificially, for example, by bombarding tungsten with energetic electrons, γ-ray mostly comes from radioactive decay of unstable elements. In the following, the term “X-ray” will be used to represent both X- and γ-ray for convenience.

To serve our purpose, a 30 keV X-ray can be chosen, for example, which penetrates the Si thickness of interest. At this energy, the dominant processes involved in the interaction between X-ray and lattice electrons are the photoelectric effect and the Compton scattering.

In the photoelectric absorption process, an incoming X-ray photon undergoes an interaction with an absorber atom in which the photon completely disappears. In its place, an energetic photoelectron is ejected by the atom from one of its bound shells. The interaction is with the atom as a whole, and cannot take place with free electrons. For photons of sufficient energy, such as those in this particular case, the most probable origin of the photoelectron is the very much tightly bound inner shells, such as the K shell, of the Si atom. The refill of electrons into these vacant inner shells then emits new photons to cause cascade generation of photoelectrons.

The interaction process of Compton scattering takes place between the incident X-ray photon and a free electron in the target material. This process is significant when the energy transfer from the photon to the target electron is much larger than that specific electron binding energy. The incoming photon is deflected through an angle with respect to its original direction. In doing so, the photon transfers a portion of its energy to the electron, which is then known as a recoil electron. Because all angles of scattering are possible, the energy transferred to the electron can vary from zero to a large fraction of the X-ray energy. Of course, the recoil electron, if of sufficient energy, can further cause electronic excitation and ionization within the target material.

The details of Compton scattering is further elaborated as follows, prior to estimating the required X-ray power. From existing literature (e.g., Evans R. D., The Atomic Nucleus, p. 684-688, McGraw-Hill, 1955), the average X-ray absorption cross section of a target is:

$${}_{e}^{}{σ}{}_{a}^{} \approx \frac{8 π}{3} {r}_{0}^{2} ( α - 4.2 {α}^{2} + 14.7 {α}^{3} + ⋯ ) {cm}^{2} \text{/} electron , \\ for α = \frac{{hv}_{0}}{{m}_{0} {c}^{2}} ⪡ 1 \qquad ( 5 )$$

where r₀ is classical electron radius, hν₀ is the incident photon energy, m₀ is rest electron mass, c is speed of light, so that m₀c²≈0.5 MeV.

The total scattering and absorption coefficient is:

$$\begin{matrix}{}_{e} σ = {}_{e}^{}{σ}{}_{a}^{} + {}_{e}^{}{σ}{}_{s}^{} \approx \frac{8 π}{3} {r}_{0}^{2} ( 1 - 2 α + 5.2 {α}^{2} - 13.3 {α}^{3} + ⋯ ) {cm}^{2} \text{/} electron , \\ for α = \frac{{hv}_{0}}{{m}_{0} {c}^{2}} ⪡ 1\end{matrix} \qquad ( 6 )$$

The average energy per Compton recoil electron is:

Tₐᵥₑ=hν₀−hν¹, or

$$\frac{{T}_{ave}}{{hv}_{0}} = 1 - \frac{{hv}^{1}}{{hv}_{0}} = 1 - \frac{{}_{e}^{}{σ}{}_{s}^{}}{{}_{e} σ} = \frac{{}_{e}^{}{σ}{}_{a}^{}}{{}_{e} σ} \approx \frac{α - 4.2 {α}^{2}}{1 - 2 α} \approx α \qquad ( 7 )$$

Putting in 30 keV for hν₀ in the above equation, we have Tₐᵥₑ≈2 keV, close to the Si K-shell electron binding energy.

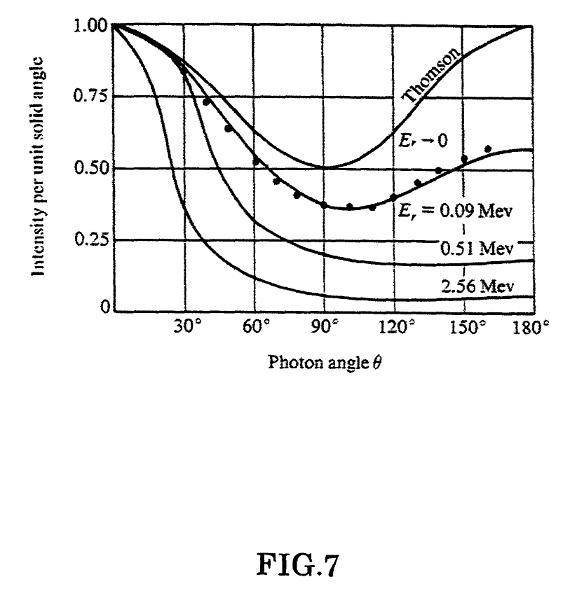

Thus, the average recoil electron has a significant kinetic energy to cause subsequent lattice ionization along the track of the X-ray, and thus to facilitate the intended purpose of generating speedy conduction electrons parallel to the proton beam. The associated X-ray scattering angle distribution is described by the Klein-Nishida formula and is plotted as in FIG. 7 (from: Meyerhof W. E., Elements of Nuclear Physics, p. 96, McGraw-Hill, 1967). For 30 keV X-ray, backscattering of photons is significant. Nevertheless, in a lot of situations of interest, the needed X-ray exposure time is very short and will not notably cause undesired defects within the target and IC devices on top. This is particularly so when the IC wafer is processed unbiased electrically. Should this photon backscattering is unfavorable in certain situations, higher energy X-ray such as above 1 MeV can be used for forward-dominant scattering as indicated by the Klein-Nishida formula (see FIG. 7).

For the total photoelectric and Compton absorption calculation, assume that each generated inner shell electron then causes about half of 2 keV/(600 eV/electron), i.e., ˜1 electron of velocity parallel and comparable to the proton velocity. Further, at the desired low temperature, the needed conduction electron number density is about 10⁵-10⁶ cm⁻³, then the total X-ray power deposition onto a spot of 2-cm diameter on the target is about 3 to 30 W. This energy load presents no difficulty to the existing cooling technology. Or, should it be otherwise in certain specific cases, it can be operated in pulsed mode during the proton irradiation of about 1-3 s. In addition, a rotational scanning treatment on a batch of IC chips or wafers can be arranged if needs be.

The fastest photo- or recoil electron carrying a kinetic energy of nearly 30 keV has a range of merely several tens of microns in Si. Accordingly, most backward propagating electrons within Si substrate, caused by the assistant radiation, will not reach the upper Si surface where IC is built, as implied by FIG. 6.

3. X-ray-assisted Deep Boron Implantation on Si and SiGe

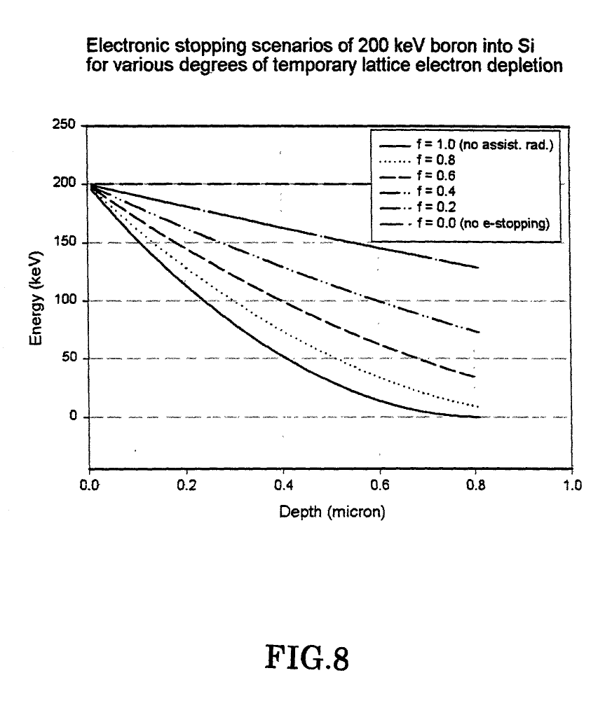

This embodiment relates to the practical case of deep boron implantation into Si or SiGe. A simulation to demonstrate the effect of the current invention on general implanter machines was conducted by numerically integrating equation (4) with a charge neutralizing multiplication parameter “f” on the right hand side, and the result is shown in FIG. 8. It is obvious that further boron shielding of various degrees (f values) can lead to desirable saving in the electronic stopping loss. For example, an X-ray-assisted 100 keV boron beam can reach the range of a conventional 200 keV sole boron beam, if f is made to be about 0.5. For the best case, i.e., f=0, this invented boron beam can have a range of about 3.4 μm within Si, totally determined by the nuclear stopping, in contrast to 0.34 μm for the traditional same energy boron beam.

While the invention has been particularly shown and described with reference to the preferred embodiments thereof, it will be understood by those skilled in the art that various changes in form and details may be made without departing from the spirit and scope of the invention. For example, in FIG. 1, target 30 can be other materials than Si, such as SiGe, SiGeC, GaAs, InGaAs, InP, plastic, etc. Particle beam 10 can be split into several particle beams of one species or many, such as proton, deuteron, helium, argon, nitrogen, Si, As, P, B, or any molecules. These applied particle species can either be electrically charged or uncharged, or changing between the two, during their whole accelerated and decelerated journey.

What is claimed is:

1. A method for achieving enhanced penetration of a particle beam within a target, comprising the steps of;
providing a target;
applying a particle beam onto a spot of said target; and
providing an assistant radiation beam onto said spot to locally cause fast conduction electrons moving at comparable velocity to said particle beam within said target;
whereby the electronic stopping loss traditionally drawn from said particle beam can now greatly reduced.

2. The method of claim 1, wherein the particle beam is composed of particles selected from atomic elements including hydrogen, deuteron, boron, nitrogen, carbon, oxygen, phosphorus, arsenic, and compounds and molecules in general.

3. The method of claim 1, wherein the particle beam is composed of particles in electrically charged states including −5, −4, −3, −2, −1, 0, +1, +2, +3, +4, +5, and with energy ranging from 250 keV to 500 MeV.

4. The method of claim 1, wherein the form of the assistant radiation can be selected from electron beam, positron beam, and electromagnetic fields including microwave, millimeter wave, infrared wave, X ray and γ ray.

5. The method of claim 1, wherein the particle beam can be made of a mixture of species and can physically be formed by several sub-beams prior to reaching a spot on the target.

6. The method of claim 1, wherein the assistant radiation can be made of a spectrum of wavelengths and can physically formed by several sub-beams prior to reaching a common spot on the target.

7. The method of claim 1, wherein the target can be selected from solids including Si, Ge, SiGe, GaAs, InP, GaN, SiC, InGaN, AlInGaN, Si₃N₄, silicon oxide, silica glass, LiNbO₃, LiTaO₃, C, and general polymers.

8. The method of claim 1, wherein the target can be selected from soft materials including biological tissues, inorganic and organic compounds.

9. The method of claim 1, wherein the target is maintained at temperature between about −270 and +100 degree C.

10. A method for greatly suppressing nuclear reactions and subsequent decay effects when injecting a particle beam into a target, comprising the steps of:
providing a target;
applying a particle beam onto a spot of said target; and
providing an auxiliary radiation beam onto said spot to locally cause fast conduction electrons moving at comparable velocity to said particle beam within said target;
whereby unwanted electronic stopping loss of said particle beam is greatly suppressed and said particle beam can now work at less acceleration energy than a traditional one, and consequently cause less nuclear reaction.

11. The method of claim 10, wherein the particle beam is composed of particles selected from atomic elements including hydrogen, deuteron, boron, nitrogen, phosphorus, arsenic, and compounds and molecules in general.

12. The method of claim 10, wherein the particle beam is composed of particles in electrically charged states including −5, −4, −3, −2, −1, 0, +1, +2, +3, +4, +5, and with energy ranging from 250 keV to 500 MeV.

13. The method of claim 10, wherein the form of the auxiliary radiation can be selected from electron beam, positron beam, and electromagnetic fields including microwave, millimeter wave, infrared wave, X ray and γ ray.

14. The method of claim 10, wherein the particle beam can be made of a mixture of species and can physically be formed by several sub-beams prior to reaching a spot on the target.

15. The method of claim 10, wherein the auxiliary radiation can be made of a spectrum of wavelengths and can physically formed by several sub-beams prior to reaching a common spot on the target.

16. A process for providing full electrical isolation between IC circuits built upon the same semiconductor substrate, and for providing high-quality IC inductors, comprising the steps of:
providing a semiconductor substrate built with IC, inductors, and predetermined isolation area;
applying an assistant radiation upon said inductors and said isolation area; and
simultaneously applying an energetic particle beam upon said inductors and said isolation area;
whereby superb signal isolation and high-quality inductors can be obtained at lower than traditional particle beam energy.

17. The process of claim 16, wherein the particle beam is composed of particles selected from atomic elements including hydrogen, deuteron, boron, nitrogen, phosphorus, arsenic, and compounds and molecules in general.

18. The process of claim 16, wherein the particle beam is composed of particles in electrically charged states including −5, −4, −3, −2, −1, 0, +1, +2, +3, +4, +5, and with energy ranging from 250 keV to 500 MeV.

19. The process of claim 16, wherein the form of the assistant radiation can be selected from electron beam, positron beam, and electromagnetic fields including microwave, millimeter wave, infrared wave, X ray and γ ray.

20. The process of claim 16, wherein the particle beam can be made of a mixture of species and can physically be formed by several sub-beams prior to reaching a spot on the target.

21. The process of claim 16, wherein the assistant radiation can be made of a spectrum of wavelengths and can physically formed by several sub-beams prior to reaching a common spot on the target.

22. The process of claim 16, wherein the target can be selected from solids including Si, Ge, SiGe, InP, GaN, SiC, InGaN, AlInGaN, LiNbO₃, LiTaO₃, and C.

23. The process of claim 16, wherein the particle beam is proton beam of 10 μA to 10 mA current at 0.5 to 30 MeV energy, the assistant radiation is electron beam of 10 μA to 10 A current at 0.5 to 30 MeV energy, and the target is silicon substrate of about 100 μm to 2 mm thickness.
